(19) United States
(12) Patent Application Publication
(10) Pub. No.: US 2024/0343932 A1
(43) Pub. Date: Oct. 17, 2024

(54) CURABLE COMPOSITION, CURED LAYER USING THE SAME AND DISPLAY DEVICE INCLUDING THE CURED LAYER

(71) Applicant: SAMSUNG SDI CO., LTD., Yongin-si (KR)

(72) Inventors: Kyunghee KANG, Suwon-si (KR); Yonghee KANG, Suwon-si (KR); Jihyeon YIM, Suwon-si (KR); Hyunjoo HAN, Suwon-si (KR); Bumjin LEE, Suwon-si (KR)

(21) Appl. No.: 18/637,269

(22) Filed: Apr. 16, 2024

(30) Foreign Application Priority Data
Apr. 17, 2023 (KR) 10-2023-0050150

(51) Int. Cl. C09D 11/50; B82Y 20/00; B82Y 40/00; C09D 11/037; C09D 11/101; C09D 11/107

(52) U.S. Cl. CPC C09D 11/50; C09D 11/037; C09D 11/101; C09D 11/107; B82Y 20/00; B82Y 40/00

(57) ABSTRACT

A curable composition including (A) quantum dots; (B) a polymerizable compound; and (C) a compound including a structural unit represented by Chemical Formula 1 and a structural unit represented by Chemical Formula 2 is provided. A cured layer produced utilizing the curable composition, and a display device including the cured layer are also provided.

### CROSS-REFERENCE TO RELATED APPLICATION

This application claims priority to and the benefit of Korean Patent Application No. 10-2023-0050150 filed on Apr. 17, 2023, in the Korean Intellectual Property Office, the entire content of which is incorporated herein by reference.

### BACKGROUND

### 1. Field

The present disclosure relates to a curable composition, a cured layer utilizing the composition, and a display device including the cured layer.

### 2. Description of the Related Art

In general, quantum dots may include surface characteristics (e.g., hydrophobicity), which limit or prevent dispersion of the quantum dots throughout a solvent. Accordingly, it is difficult to introduce quantum dots into a polar solvent system that includes other components such as a binder or a curable monomer.

For example, even in the case of a quantum dot ink composition being actively researched, a polarity of the composition is relatively low in an initial step (process) and the composition may require being (e.g., may still need to be uniformly) dispersed in a solvent utilized in a curable composition having a high hydrophobicity. Because it is difficult to achieve a content of 20 wt %, or more, of the quantum dots based on a total amount of the composition, it may be impossible to increase light efficiency of the ink over a certain level. Even though the quantum dots are additionally added and dispersed in order to increase light efficiency, the resultant viscosity may then exceed a range (e.g., about 12 (cPs)) capable of, or suitable for, ink-jetting and thus proper processability may not be satisfied or achieved.

In order to achieve a viscosity range capable of, or suitable for, ink-jetting, an ink solid content (e.g., amount) may be lowered by dissolving (e.g., including) a solvent in quantities of about 50 wt % (or more) based on a total amount of the composition. The additional solvent may also provide a somewhat satisfactory result in terms of viscosity, but nozzle drying due to solvent volatilization, nozzle clogging, and/or a thickness reduction of a single layer (e.g., over time after jetting) may become worse. Therefore, in applications to actual processes, it is difficult to control a thickness deviation after curing, and it is difficult to control the viscosity range of the quantum dot ink composition by adding additional solvent.

Accordingly, a solvent-free quantum dot ink composition that does not include a solvent may be the most desirable form to be applied to an actual process. The current technique of applying a quantum dot itself to a solvent-type or kind composition is now limited to a certain extent.

As reported so far, it is difficult to increase light efficiency and absorption rate due to the limits of viscosity and the amount of quantum dots if (e.g. when) utilizing desirable solvent-type or kind of compositions for application to the actual process. Other approaches to improvement that have been made to lower the content (e.g., amount) of the quantum dots and increase the content (e.g., amount) of a light diffusing agent (scatterer) have also failed to solve difficulties associated with precipitation and a low light efficiency.

Successful implementation of a solvent-free curable composition (i.e., quantum dot ink composition) requires (or there is a growing desire for) a solvent-free composition. In the case of a solvent-free composition, light resistance reliability improvement is urgently needed, such as pattern detachment due to a decrease in adhesion between the curing step (process) and/or in subsequent processes due to high shrinkage during curing.

### SUMMARY

One or more aspects of embodiments of the present disclosure are directed toward curable composition having excellent or suitable light resistance reliability.

One or more aspects of embodiments of the present disclosure are directed toward a cured layer produced utilizing the curable composition.

One or more aspects of embodiments of the present disclosure are directed toward a display device including the cured layer.

One or more embodiments provide a curable composition including (A) quantum dots; (B) a polymerizable compound; and (C) a compound including a structural unit represented by Chemical Formula 1 and a structural unit represented by Chemical Formula 2.

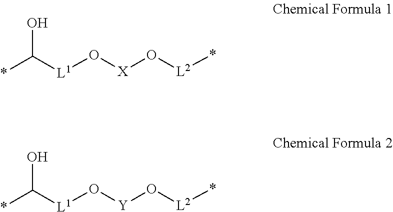

In Chemical Formulas 1 and 2,
L¹ and L² may each independently be a substituted or unsubstituted C1 to C20 alkylene group, and
X and Y may each independently be a substituted or unsubstituted C6 to C20 arylene group, or a divalent linking group including a substituted or unsubstituted C6 to C20 arylene group, and X and Y are different from each other.

In some embodiments, X and Y may each independently be represented by any one of Chemical Formulas L-1 to L-14.

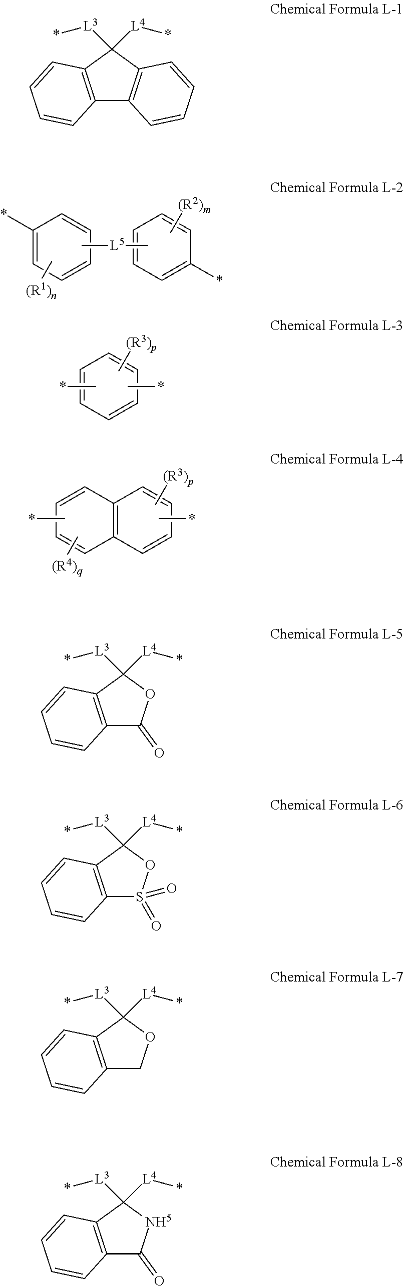

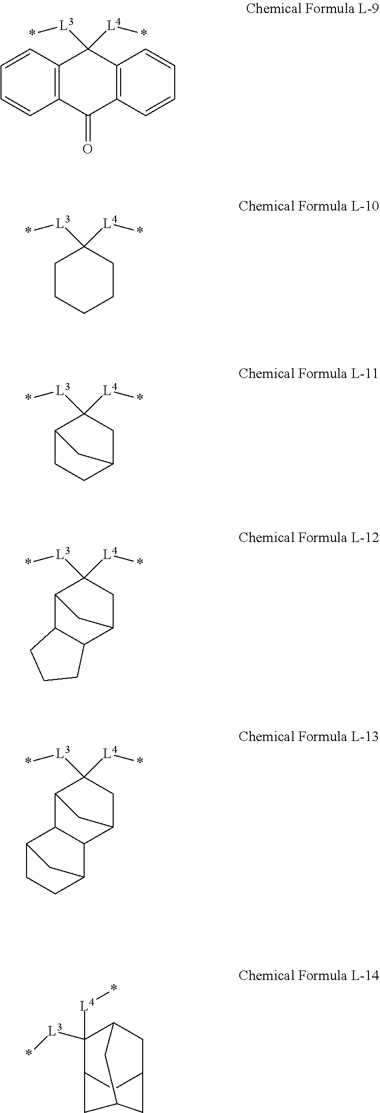

In Chemical Formulas L-1 to L-14,
L³ and L⁴ may each independently be a substituted or unsubstituted C6 to C20 arylene group,
L⁵ may be a single bond, a substituted or unsubstituted C1 to C20 alkylene group, or a substituted or unsubstituted C6 to C20 arylene group,
R¹ to R⁵ may each independently be a hydrogen atom, a substituted or unsubstituted C1 to C20 alkyl group, a vinyl group, or a substituted or unsubstituted C6 to C20 aryl group, and
m, n, p, and q may each independently be an integer of 0 to 3.
X and Y may each independently be represented by any one of Chemical Formulas L-1 to L-4.

The compound including the structural unit represented by Chemical Formula 1 and the structural unit represented by Chemical Formula 2 may have a weight average molecular weight of about 1,000 gram per mole (g/mol) to about 30,000 g/mol.

The compound including the structural unit represented by Chemical Formula 1 and the structural unit represented by Chemical Formula 2 may be included in an amount of about 1 wt % to about 40 wt % based on a total amount of solids of (e.g., constituting) the curable composition.

The polymerizable compound may further include a compound represented by Chemical Formula 3.

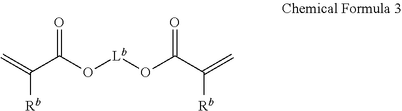

In Chemical Formula 3,
each R^{b} independently may be a hydrogen atom or a methyl group, and
L^{b} may be a substituted or unsubstituted C1 to C30 alkylene group or *-L^{c}-O-L^{d}-*, wherein L^{c} and L^{d} may each independently be a substituted or unsubstituted C1 to C20 alkylene group.

The compound represented by Chemical Formula 3 may be represented by Chemical Formula 3-1 or 3-2.

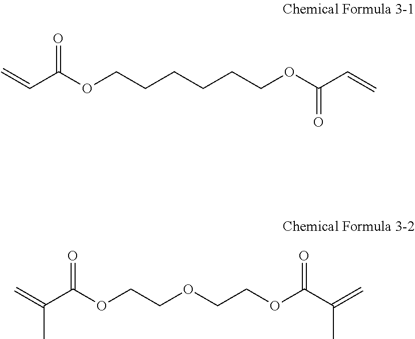

The quantum dots may be surface-modified quantum dots represented by at least one of Chemical Formulas 4 to 17.

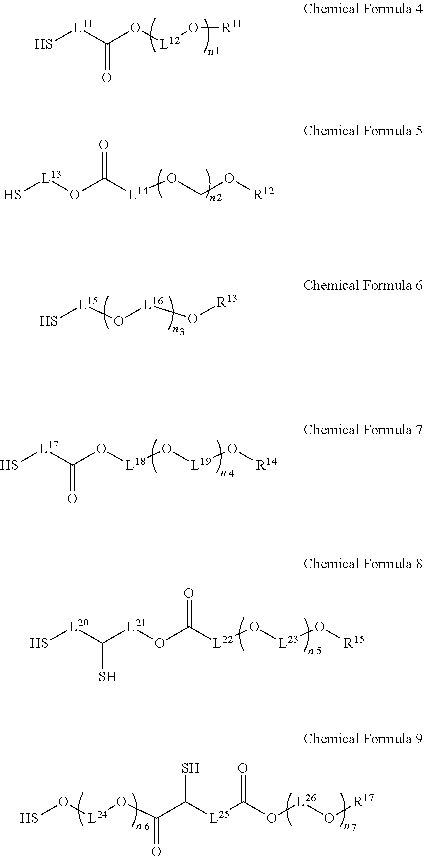

In Chemical Formulas 4 to 9,
R¹¹ to R¹⁷ may each independently be a substituted or unsubstituted C1 to C10 alkyl group or a substituted or unsubstituted C6 to C20 aryl group,
L¹¹ to L²⁶ may each independently be a substituted or unsubstituted C1 to C10 alkylene group, and
n1 to n7 may each independently be an integer of 0 to 10,

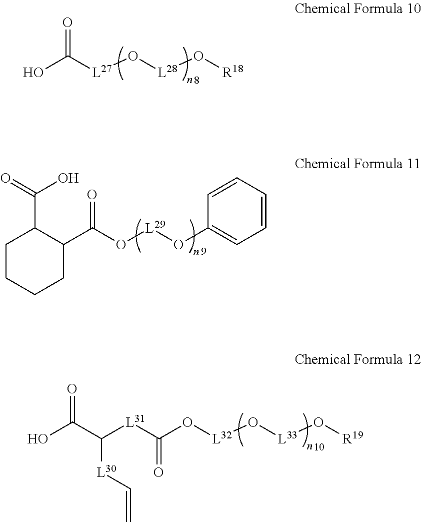

wherein, in Chemical Formulas 10 to 12,
R¹⁸ and R¹⁹ may each independently be a substituted or unsubstituted C1 to C10 alkyl group,
L²⁷ to L³³ may each independently be a substituted or unsubstituted C1 to C10 alkylene group, and
n8 to n10 may each independently be an integer of 0 to 10,

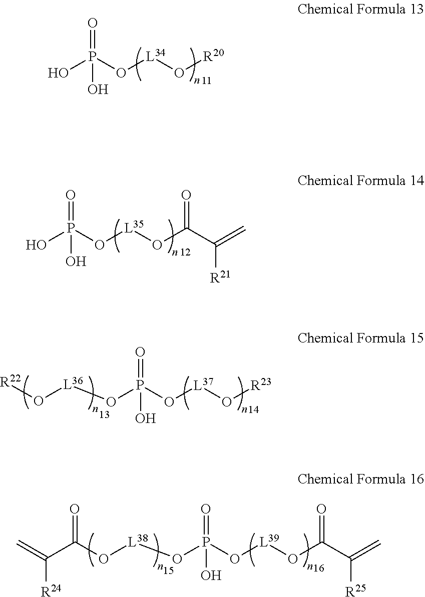

wherein, in Chemical Formulas 13 to 16,
R²⁰ to R²⁵ may each independently be a hydrogen atom or a substituted or unsubstituted C1 to C10 alkyl group,
L³⁴ to L³⁹ may each independently be a substituted or unsubstituted C1 to C10 alkylene group, and
n11 to n16 may each independently be an integer of 0 to 10,

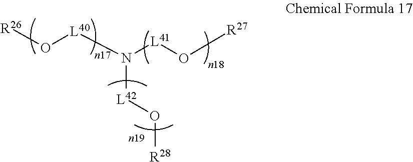

wherein, in Chemical Formula 17,
R²⁶ to R²⁸ may each independently be a substituted or unsubstituted C1 to C10 alkyl group,
L⁴⁰ to L⁴² may each independently be a substituted or unsubstituted C1 to C10 alkylene group, and
n17 to n19 may each independently be an integer of 0 to 10.

The quantum dots may have a maximum fluorescence emission wavelength at about 500 nanometer (nm) to about 680 nm.

The curable composition may be a solvent-free curable composition.

The quantum dots may be included in an amount of about 5 wt % to about 70 wt % based on a total weight of the solvent-free curable composition.

The polymerizable compound may be included in an amount of about 30 wt % to about 95 wt % based on a total weight of the solvent-free curable composition.

The curable composition may further include a polymerization initiator, a light diffusing agent, or a combination thereof.

The light diffusing agent may include barium sulfate, calcium carbonate, titanium dioxide, zirconia, or a combination thereof.

The curable composition may further include a solvent.

The curable composition may include about 1 wt % to about 40 wt % of the (A) quantum dots; about 1 wt % to about 20 wt % of the (B) polymerizable compound; (C) about 0.1 wt % to about 20 wt % of the compound including the structural unit represented by Chemical Formula 1 and the structural unit represented by Chemical Formula 2; and about 40 wt % to about 80 wt % of the solvent based on a total weight of the curable composition.

The curable composition may further include at least one of a polymerization inhibitor; malonic acid; 3-amino-1,2-propanediol; a silane-based coupling agent; a leveling agent; a fluorine-based surfactant; or a combination thereof.

Other embodiments provide a cured layer produced utilizing the curable composition.

Other embodiments provide a display device including the cured layer.

Other embodiments of the present disclosure are included or provide in more detail in the following detailed description.

By including a compound including a structural unit disclosed herein (e.g., as an essential component), a curable composition with significantly improved light resistance reliability may be provided.

### DETAILED DESCRIPTION

Hereinafter, embodiments of the present disclosure are described in more detail. However, these embodiments serve as only as examples, the present disclosure is not limited thereto and the present disclosure is defined by the scope of claims. In this regard, the present embodiments may have different forms and should not be construed as being limited to the descriptions set forth herein, and it is to be appreciated that all changes, equivalents, and substitutes that do not depart from the spirit and technical scope are encompassed in the present disclosure.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe various elements, these elements should not be limited by these terms. These terms are only used to distinguish one element from another element. Thus, a first element could be termed a second element without departing from the teachings of the present disclosure. Similarly, a second element could be termed a first element.

As used herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, alternative language such as “or” is not to be construed as an exclusive meaning, for example, “A or B” is construed to include A, B, A+B, and/or the like. Similarly, the term “and/or” includes any and all combinations of one or more of the associated listed items. The symbol “/” utilized herein may be interpreted as “and” or “or” according to the context.

In the present specification It will be understood that if (e.g., when) an element such as a layer, film, region, or substrate is referred to as being “on” another element, it may be directly on the other element or intervening elements may also be present. In contrast, if (e.g., when) an element is referred to as being “directly on” another element, there are no intervening elements present.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added. The term “combination thereof” may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element.

In this context, “consisting essentially of” means that any additional components will not materially affect the chemical, physical, optical or electrical properties of the semiconductor film.

### Definitions

As utilized herein, if (e.g. when) specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As utilized herein, if (e.g. when) specific definition is not otherwise provided, “substituted” refers to replacement of at least one hydrogen atom by a substituent selected from among a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As utilized herein, if (e.g. when) specific definition is not otherwise provided, “hetero” refers to inclusion of at least one heteroatom of N, O, S, and P, in the chemical formula.

As utilized herein, if (e.g. when) specific definition is not otherwise provided, “(meth)acrylate” refers to both (e.g., simultaneously) “acrylate” and “methacrylate”, and “(meth)acrylic acid” refers to “acrylic acid” and “methacrylic acid”.

As utilized herein, if (e.g. when) specific definition is not otherwise provided, the term “combination” refers to mixing or copolymerization.

As utilized herein, if (e.g. when) a definition is not otherwise provided, hydrogen is bonded at the position if (e.g. when) a chemical bond is not drawn in a chemical formula where one otherwise may supposed to be given.

In some embodiments, as utilized herein, if (e.g. when) a definition is not otherwise provided, “*” refers to a linking point with the same or different atom or chemical formula. For example, “*” may be a linking point with a different atom, a same chemical formula, or a different chemical formula.

In the present disclosure, if (e.g., when) dots or particles are spherical, the term “diameter” indicates a particle diameter or an average particle diameter, and if (e.g., when) the dots or particles are non-spherical, the term “diameter” indicates a major axis length or an average major axis length. In some embodiments, the average particle diameter may be measured by a method well suitable to those skilled in the art, for example, may be measured by a particle size analyzer, or may be measured by a transmission electron microscopic image or a scanning electron microscopic image. In some embodiments, it is possible to obtain an average particle diameter value by measuring utilizing a dynamic light scattering method, performing data analysis, counting the number of particles for each particle size range, and calculating from this. As utilized herein, if (e.g., when) a definition is not otherwise provided, the average particle diameter may refer to a diameter (D50) of particles having a cumulative volume of 50 vol % in a particle size distribution.

### Curable Composition

The curable composition according to some embodiments includes (A) quantum dots; (B) a polymerizable compound; and (C) a compound including a structural unit represented by Chemical Formula 1 and a structural unit represented by Chemical Formula 2.

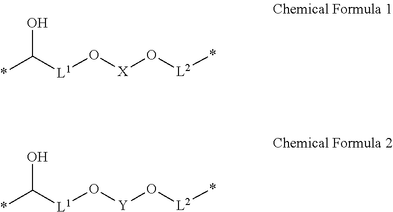

In Chemical Formulas 1 and 2,
L¹ and L² may each independently be a substituted or unsubstituted C1 to C20 alkylene group, and
X and Y may each independently be a substituted or unsubstituted C6 to C20 arylene group, or a divalent linking group including a substituted or unsubstituted C6 to C20 arylene group, and X and Y are different from each other.

The present disclosure relates to a photosensitive resin composition for a color filter applied to a display including quantum dots (QD), for example, a curable composition (ink composition) including quantum dots.

In general, in order to provide (e.g., secure) dispersibility of the quantum dots, a solvent is utilized to disperse the quantum dots, which may cause nozzle drying, deterioration of ink-jetting processibility, marginal efficiency (e.g., light efficiency) due to limitations of an injectable content (e.g., amount) of the quantum dots, and/or the like. To improve the performance of a quantum dot ink composition, efforts to develop a solvent-free quantum dot ink composition (e.g., including no solvent) have been made, but technology for dispersing the quantum dots alone (e.g., themselves) in a solvent-free quantum dot ink composition is limited. For example, the injectable content (e.g., amount) of the quantum dots into the composition reaches a limit of about 20 wt % to about 25 wt %, and it is difficult to improve optical characteristics to a higher level.

Efforts to implement a quantum dot ink composition with superior performance have sought to apply a high content (e.g., amount) of solid quantum dots in a solvent-free composition through surface-modification of the quantum dots have resulted in an inevitable increase of the viscosity of the composition, which causes significant deterioration of ink-jetting properties. The reduction of the increased viscosity to a level suitable for ink-jet applications, requires (or there is a desire for) methods of reducing a solid content (e.g., amount) of the quantum dots, increasing a temperature of a the ink-jet head (e.g., through which an ink is jetted), and/or the like. However, if (e.g. when) the solid content (e.g., amount) of the quantum dots is reduced, optical characteristics may be deteriorated, and if (e.g. when) the temperature of the inkjet head is increased, ejection properties during the ink-jet process may be deteriorated, causing inferior adhesion.

Furthermore, recently, electrohydrodynamic (EHD) jet printing technology has emerged. This is a direct-writing method of discharging (e.g., jetting) an ink through an electrohydrodynamic force by utilizing an electric field. EHD jet printing technology has the advantages of nano-scale high-resolution characteristics, a fast printing speed, an application range of one or more suitable inks, and/or the like. As compared with the suitable ink jet printing methods, and because micro- or nano-sized structures and patterns in one or more suitable shapes and sizes may be manufactured by utilizing this technology, EHD jet printing is attracting attention as a next-generation printing technology.

Accordingly, the present disclosure relates to well-tested research by the present inventive entity that provides a curable composition having very excellent or suitable sedimentation stability and optical characteristics (light efficiency). For example, very excellent or suitable light resistance reliability may be provided by designing a high molecular weight compound having at least one structural unit, as described herein, included in the composition. The curable composition according to some embodiments has excellent or suitable immersion stability and light resistance reliability despite high viscosity and thus may be applied to the aforementioned electrohydrodynamic (EHD) jet printing method.

Hereinafter, each component of the curable composition is described in more detail.

### Compound Including Structural Unit Represented by Chemical Formula 1 and Structural Unit Represented by Chemical Formula 2

The curable composition according to some embodiments includes, (e.g., as an essential component), a compound including both (e.g., simultaneously) the structural unit represented by Chemical Formula 1 and the structural unit represented by Chemical Formula 2. In some embodiments including the two structural units simultaneously greatly improves sedimentation stability and optical characteristics (light resistance reliability) while concurrently (e.g., simultaneously) increasing a viscosity of the curable composition.

X of Chemical Formula 1 and Y of Chemical Formula 2 may each independently be an arylene group or a divalent linking group including an arylene group, and may be for example represented by any one of Chemical Formulas L-1 to L-14.

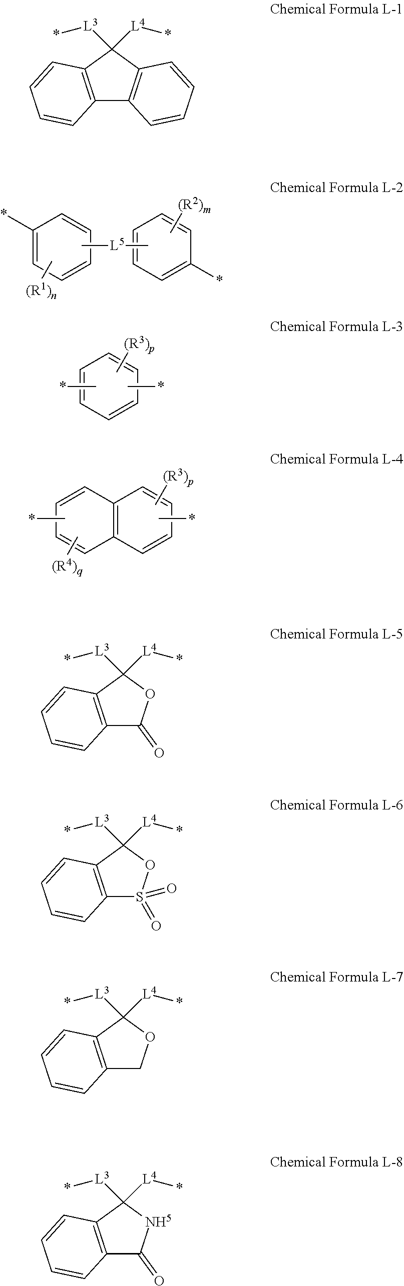

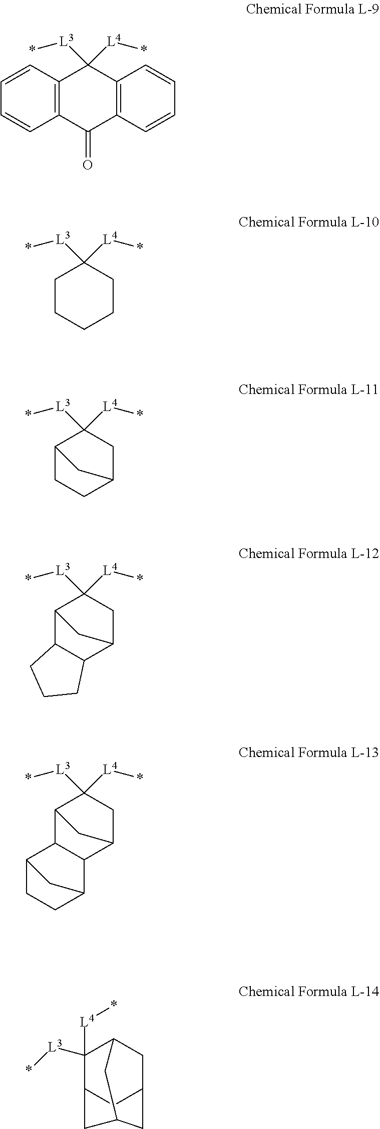

In Chemical Formulas L-1 to L-14,
L³ and L⁴ may each independently be a substituted or unsubstituted C6 to C20 arylene group,
L⁵ may be a single bond, a substituted or unsubstituted C1 to C20 alkylene group, or a substituted or unsubstituted C6 to C20 arylene group,
R¹ to R⁵ may each independently be a hydrogen atom, a substituted or unsubstituted C1 to C20 alkyl group, a vinyl group, or a substituted or unsubstituted C6 to C20 aryl group, and
m, n, p, and q may each independently be an integer of 0 to 3.

For example, X and Y may each independently be represented by any one of Chemical Formulas L-1 to L-4. In this case, a degree of improvement in light resistance reliability of the curable composition according to some embodiments may be the best.

For example, the compound including the structural unit represented by Chemical Formula 1 and the structural unit represented by Chemical Formula 2 may have a weight average molecular weight of about 1,000 g/mol to about 30,000 g/mol, for example, about 1,000 g/mol to about 10,000 g/mol. If (e.g. when) the weight average molecular weight of the compound including the structural units represented by Chemical Formulas 1 and 2 is within the described ranges, the viscosity of the curable composition may be prevented or reduced from being too low. In the comparable ink-jet printing process and the electrohydrodynamic (EHD) jet printing process, if (e.g. when) the curable composition has too low a viscosity, smooth printing is not performed. In some embodiments, the curable composition desirably may have a viscosity at which ink-jet printing is possible, for example, a viscosity of about 5 centipoise (cPs) to about 20 cPs.

For example, the compound including the structural unit represented by Chemical Formula 1 and the structural unit represented by Chemical Formula 2 may be included in an amount of about 1 wt % to about 40 wt %, for example, about 3 wt % to about 30 wt % based on a total amount of solids constituting the curable composition (solvent-free curable composition). If (e.g. when) the solid content (e.g., amount) of the compound including the structural units represented by Chemical Formulas 1 and 2 is within the described range, the light resistance reliability of the curable composition can be greatly improved and the sedimentation stability of the quantum dots can also be improved.

For example, the curable composition according to some embodiments may be a solvent-free curable composition or a solvent-type or kind curable composition including a solvent.

For example, if (e.g. when) the curable composition according to some embodiments is a solvent-type or kind curable composition including a solvent, the compound including the structural unit represented by Chemical Formula 1 and the structural unit represented by Chemical Formula 2 may be included in an amount of about 0.1 wt % to about 20 wt % based on a total amount of the solvent-type or kind curable composition.

### Quantum Dots

The quantum dots in the curable composition according to some embodiments may be quantum dots that are surface-modified with a ligand having a polar group, for example, a ligand having a high affinity for, or with, the polymerizable compound. In the case of the surface-modified quantum dots as described, it is very easy to prepare a high-concentration or highly-concentrated quantum dot dispersion (e.g., thereby improving the dispersibility of the quantum dots in the polymerizable compound). The high-concentration or highly-concentrated quantum dot dispersion may have a great effect on improving the light efficiency and, for example, may be advantageous to implement a solvent-free curable composition.

For example, the ligand having the polar group may have a structure having high affinity for, or with, the chemical structure of the polymerizable compound.

For example, the ligand having the polar group may be any one of the compounds represented by Chemical Formulas 4 to 17, or a combination thereof, but is not necessarily limited thereto.

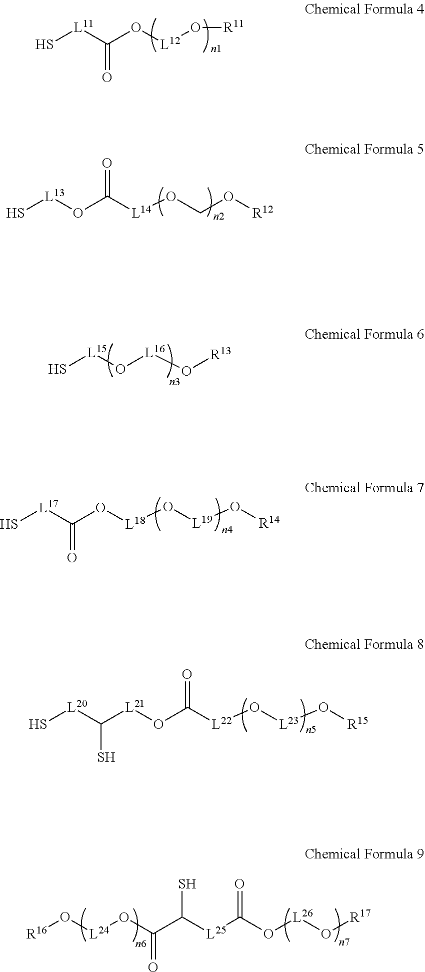

In Chemical Formulas 4 to 9,
R¹¹ to R¹⁷ may each independently be a substituted or unsubstituted C1 to C10 alkyl group or a substituted or unsubstituted C6 to C20 aryl group,
L¹¹ to L²⁶ may each independently be a substituted or unsubstituted C1 to C10 alkylene group, and
n1 to n7 may each independently be an integer of 0 to 10,

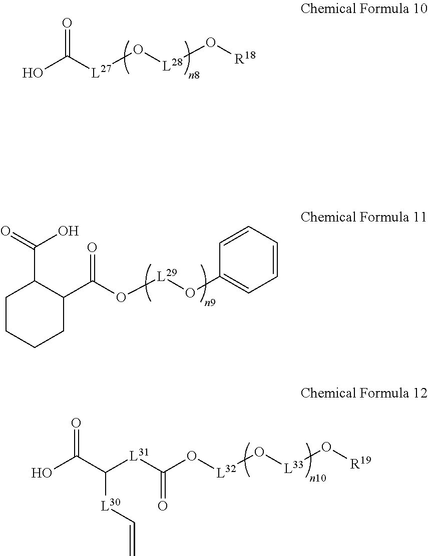

wherein, in Chemical Formula 10 to 12,
R¹⁸ and R¹⁹ may each independently be a substituted or unsubstituted C1 to C10 alkyl group,
L²⁷ to L³³ may each independently be a substituted or unsubstituted C1 to C10 alkylene group, and
n8 to n10 may each independently be an integer of 0 to 10,

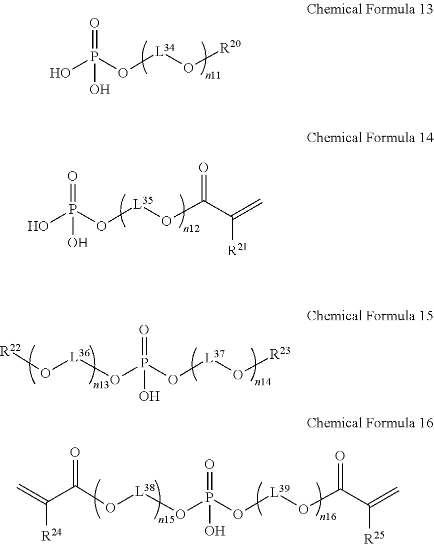

wherein, in Chemical Formulas 13 to 16,
R²⁰ to R²⁵ may each independently be a hydrogen atom or a substituted or unsubstituted C1 to C10 alkyl group,
L³⁴ to L³⁹ may each independently be a substituted or unsubstituted C1 to C10 alkylene group, and
n11 to n16 may each independently be an integer of 0 to 10,

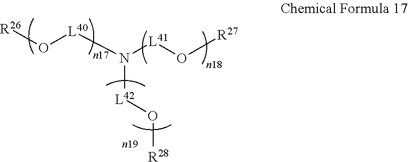

wherein, in Chemical Formula 17,
R²⁶ to R²⁸ may each independently be a substituted or unsubstituted C1 to C10 alkyl group,
L⁴⁰ to L⁴² may each independently be a substituted or unsubstituted C1 to C10 alkylene group, and
n17 to n19 may each independently be an integer of 0 to 10.

For example, the compounds represented by Chemical Formulas 4 to 17 may be represented by any one of the compounds represented by Chemical Formulas A to Q, but are not necessarily limited thereto.

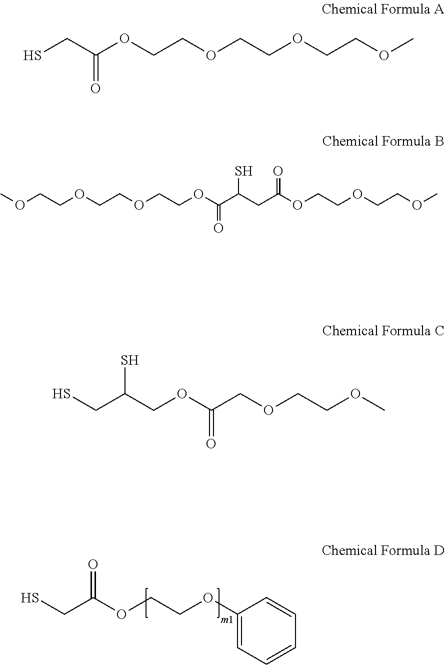

In Chemical Formula D, m1 may be an integer from 0 to 10.

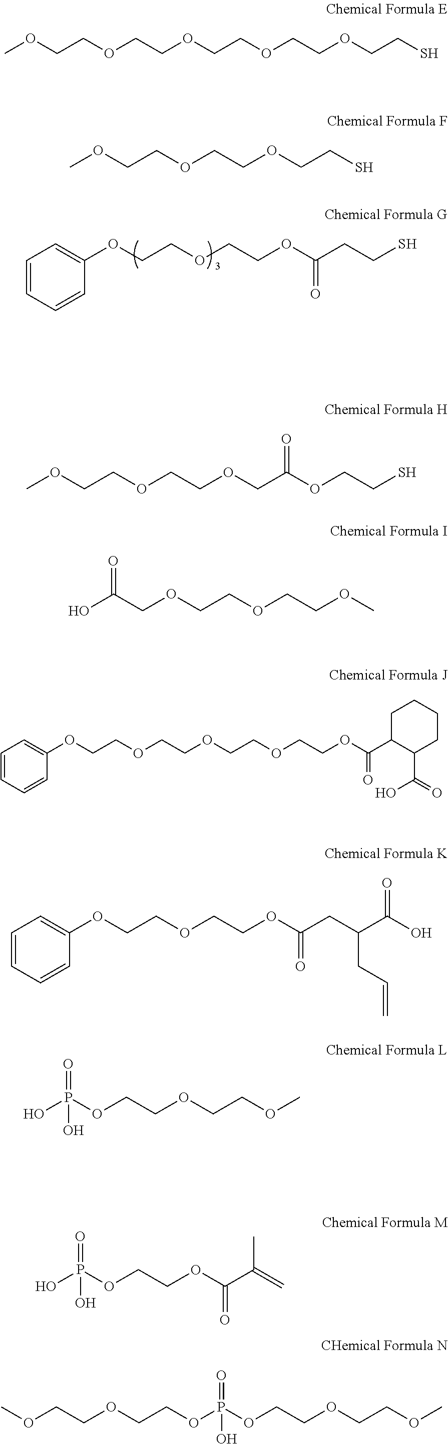

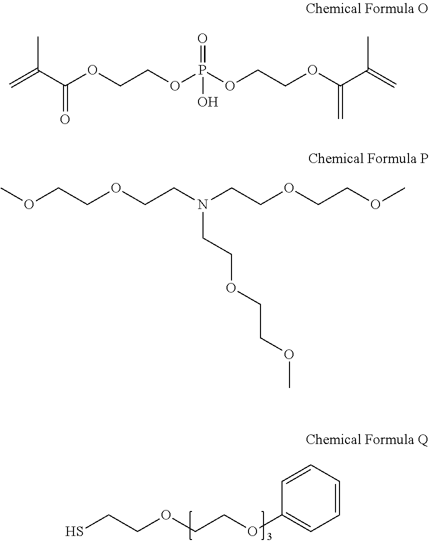

If (e.g. when) the ligand having the polar group is utilized, the surface modification of the quantum dots is easier to achieve. If (e.g. when) the quantum dots surface-modified with the ligand having the polar group are added to the described polymerizable compound and stirred, a very transparent dispersion may be obtained, which indicates that the surface modification of the quantum dots is very good or suitable.

For example, if (e.g. when) the curable composition according to some embodiments is a solvent-free curable composition, the quantum dots may be included in an amount of about 5 wt % to about 70 wt %, for example about 10 wt % to about 60 wt %, for example about 20 wt % to about 60 wt %, for example about 30 wt % to about 50 wt %. If (e.g. when) the quantum dots are included within the described range, a high light retention rate and light efficiency can be achieved, e.g., even after curing.

For example, if (e.g. when) the curable composition according to some embodiments is a solvent-type or kind curable composition including a solvent, the quantum dots may be included in an amount of about 1 wt % to about 40 wt %, for example, about 3 wt % to about 30 wt %, based on a total amount of the curable composition. If (e.g. when) the quantum dots are included within the described range, the light conversion rate is improved and pattern characteristics and development characteristics are not impaired, so that excellent or suitable processibility may be obtained.

For example, the quantum dots may absorb light in a wavelength region of about 360 nanometer (nm) to about 780 nm, for example about 400 nm to about 780 nm and may emit (e.g., be configured to emit) fluorescence in a wavelength region of about 500 nm to about 700 nm, for example about 500 nm to about 580 nm. In some embodiments, the quantum dots may emit (e.g., be configured to emit) fluorescence in a wavelength region of about 600 nm to about 680 nm. For example, the quantum dots may have a maximum fluorescence emission wavelength (fluorescence λₑₘ) at about 500 nm to about 680 nm.

The quantum dots may each independently have a full width at half maximum (FWHM) of about 20 nm to about 100 nm, for example about 20 nm to about 50 nm. If (e.g. when) the quantum dots have a full width at half maximum (FWHM) of the ranges described herein, color reproducibility may be increased if (e.g. when) utilized as a color material in a color filter, e.g., due to high color purity.

The quantum dots may each independently be an organic material, an inorganic material, or a hybrid (mixture) of an organic material and an inorganic material.

The quantum dots may each independently be composed of a core and a shell around (e.g., surrounding) the core. In some embodiments, the core and the shell may each independently have a structure of a core, core/shell, core/first shell/second shell, alloy, alloy/shell, and/or the like. In some embodiments, the structure may be composed of Group II-IV, Group Ill-V, and/or the like, but are not limited thereto.

For example, the core may include at least one material selected from among CdS, CdSe, CdTe, ZnS, ZnSe, ZnTe, HgS, HgSe, HgTe, GaN, GaP, GaAs, InP, InAs, and an alloy thereof, but is not necessarily limited thereto. The shell around (e.g., surrounding) the core may include at least one material selected from among CdSe, ZnSe, ZnS, ZnTe, CdTe, PbS, TiO, SrSe, HgSe, and an alloy thereof, but is not necessarily limited thereto.

In some embodiments, because an interest in an environmental impact has been recently much increased over the whole world, and a restriction of a toxic material also has been fortified, the core may be a cadmium-free light emitting material (InP/ZnS, InP/ZnSe/ZnS, and/or the like) but is not necessarily limited thereto. For example, the cadmium-free light emitting material may have little (e.g., low) quantum efficiency (quantum yield) but may be environmentally-friendly as compared to (e.g., instead of) a light emitting material having a cadmium-based core.

In the case of the quantum dots of the core/shell structure, an entire size including the shell (an average particle diameter) may be about 1 nm to about 15 nm, for example, about 5 nm to about 15 nm.

For example, the quantum dots may each independently include red quantum dots, green quantum dots, or a combination thereof. The red quantum dots may each independently have an average particle diameter of about 10 nm to about 15 nm. The green quantum dots may each independently have an average particle diameter of about 5 nm to about 8 nm.

On the other hand, for dispersion stability of the quantum dot, the curable composition according to some embodiments may further include a dispersant. The dispersant promotes (e.g., helps) substantially uniform dispersibility of light conversion materials such as quantum dots in the curable composition and may include a non-ionic, anionic, or cationic dispersant. For example, the dispersant may be polyalkylene glycol or esters thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, alkyl amide alkylene oxide addition product, alkyl amine and/or the like, and they may be utilized alone or in a mixture of two or more. The dispersant may be utilized in an amount of about 0.1 wt % to about 100 wt %, for example about 10 wt % to about 20 wt % based on a solid content (e.g., amount) of the light conversion material such as quantum dots.

### Polymerizable Compound

The curable composition according to some embodiments may include a polymerizable compound, and the polymerizable compound may have a carbon-carbon double bond at its terminal end.

The polymerizable compound having the carbon-carbon double bond at the terminal end may be included in an amount of about 30 wt % to about 95 wt %, for example, about 50 wt % to about 90 wt %, based on a total amount of the solvent-free curable composition. If (e.g. when) the polymerizable compound having the carbon-carbon double bond at the terminal end is included within the ranges, a solvent-free curable composition having a viscosity that enables ink-jetting may be prepared and the quantum dots in the prepared solvent-free curable composition may have improved dispersibility, thereby improving optical characteristics.

For example, the polymerizable compound having the carbon-carbon double bond at the terminal end may have a molecular weight of about 170 g/mol to about 1,000 g/mol. If (e.g. when) the polymerizable compound having the carbon-carbon double bond at the terminal end has a molecular weight within the range, it may be advantageous for ink-jetting because it does not increase a viscosity of the composition without hindering the optical characteristics of the quantum dots.

For example, the polymerizable compound having the carbon-carbon double bond at the terminal end may be represented by Chemical Formula 3, but is not necessarily limited thereto.

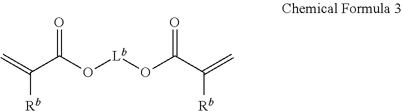

In Chemical Formula 3,
each R^{b} independently may be a hydrogen atom or a methyl group, and
L^{b} may be a substituted or unsubstituted C1 to C30 alkylene group or *-L^{c}-O-L^{d}-*, wherein L^{c} and L^{d} may each independently be a substituted or unsubstituted C1 to C20 alkylene group.

Examples of the polymerizable compound having the carbon-carbon double bond at the terminal end may be represented by Chemical Formula 3-1 or 3-2, but is not necessarily limited thereto.

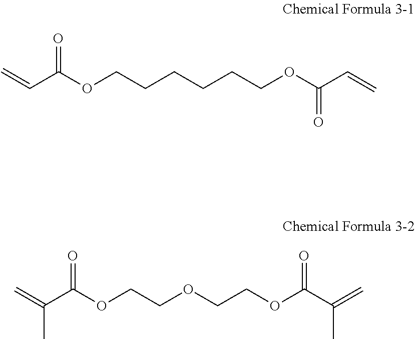

Examples of the polymerizable compound having the carbon-carbon double bond at the terminal end may further include ethylene glycoldiacrylate, triethylene glycoldiacrylate, 1,4-butanedioldiacrylate, 1,6-hexanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, pentaerythritolhexaacrylate, bisphenol A diacrylate, trimethylolpropanetriacrylate, novolac epoxyacrylate, ethylene glycoldimethacrylate, triethylene glycoldimethacrylate, propylene glycoldimethacrylate, 1,4-butanedioldimethacrylate, 1,6-hexanedioldimethacrylate, or one or more combinations thereof, in addition to the aforementioned compound of Chemical Formula 3-1 or 3-2.

In some embodiments, together with the polymerizable compound having the carbon-carbon double bond at the terminal end, a generally-utilized monomer of a thermosetting or photocurable composition may be further included. For example the monomer may further include an oxetane-based compound such as bis[1-ethyl (3-oxetanyl)]methyl ether, and/or the like.

In some embodiments, if (e.g. when) the curable composition is a solvent-type or kind curable composition including a solvent, the polymerizable compound may be included in an amount of about 1 wt % to about 20 wt %, about 1 wt % to about 15 wt %, for example, about 5 wt % to about 15 wt % based on a total amount of the solvent-type or kind curable composition. If (e.g. when) the polymerizable compound is included within the described range, optical properties of the quantum dot may be improved.

### Light Diffusing Agent

The curable composition according to some embodiments may further include a light diffusing agent.

Examples of the light diffusing agent may include barium sulfate (BaSO₄), calcium carbonate (CaCO₃), titanium dioxide (TiO₂), zirconia (ZrO₂), or a combination thereof.

The light diffusing agent may reflect unabsorbed light in the aforementioned quantum dots and allows the quantum dots to absorb the reflected light again. For example, the light diffusing agent may increase an amount of light absorbed by the quantum dots and increase light conversion efficiency of the curable composition.

The light diffusing agent may have an average particle diameter (D₅₀) of about 150 nm to about 250 nm, and specifically about 180 nm to about 230 nm. If (e.g. when) the average particle diameter of the light diffusing agent is within the described ranges, it may have a better light diffusing effect and increase light conversion efficiency.

The light diffusing agent may be included in an amount of about 1 wt % to about 20 wt %, for example, about 2 wt % to about 15 wt %, for example, about 3 wt % to about 10 wt % based on a total amount of the curable composition. If (e.g. when) the light diffusing agent is included in an amount of less than about 1 wt % based on a total amount of the curable composition, it is difficult to achieve (e.g., expect) a light conversion efficiency improvement effect due to the utilization of the light diffusing agent, while if (e.g. when) it is included in an amount of greater than about 20 wt %, there is a possibility that the quantum dots may be sedimented.

### Polymerization Initiator

The curable composition according to some embodiments may further include a polymerization initiator, for example, a photopolymerization initiator, a thermal polymerization initiator, or a combination thereof.

The photopolymerization initiator is a generally-utilized initiator for a curable composition, examples of which may be an acetophenone-based compound, a benzophenone-based compound, a thioxanthone-based compound, a benzoin-based compound, a triazine-based compound, an oxime-based compound, an aminoketone-based compound, and/or the like, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and/or the like.

Examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and/or the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and/or the like.

Examples of the benzoin-based compound may be benzoin, benzoin methyl ether, benzoin ethyl ether, benzoin isopropyl ether, benzoin isobutyl ether, benzyldimethylketal, and/or the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and/or the like.

Examples of the oxime-based compound may be O-acyloxime-based compound, 2-(O-benzoyloxime)-1-[4-(phenylthio)phenyl]-1,2-octandione, 1-(0-acetyloxime)-1-[9-ethyl-6-(2-methylbenzoyl)-9H-carbazol-3-yl]ethanone, O-ethoxycarbonyl-α-oxyamino-1-phenylpropan-1-one, and/or the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and/or the like.

Examples of the aminoketone-based compound may be 2-benzyl-2-dimethylamino-1-(4-morpholinophenyl)-butanone-1, and/or the like.

The photopolymerization initiator may further include a carbazole-based compound, a diketone-based compound, a sulfonium borate-based compound, a diazo-based compound, an imidazole-based compound, a diimidazole-based compound, and/or the like, besides the compounds.

The photopolymerization initiator may be utilized with a photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and/or the like.

Examples of the thermal polymerization initiator may be peroxide, specifically benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis(isobutyronitrile), t-butyl perbenzoate, and/or the like, for example 2,2′-azobis-2-methylpropinonitrile, but are not necessarily limited thereto and any of which is well suitable in the art may be utilized.

The polymerization initiator may be included in an amount of about 0.01 wt % to about 5 wt %, for example about 0.1 wt % to about 3 wt % based on a total amount of the curable composition. If (e.g. when) the polymerization initiator is included in the ranges, it is possible to obtain excellent or suitable reliability due to sufficient curing during exposure or thermal curing and to prevent or reduce deterioration of transmittance due to non-reaction initiators, thereby preventing or reducing deterioration of optical characteristics of the quantum dots.

### Other Additives

For stability and dispersion improvement of the quantum dot, the curable composition according to some embodiments may further include a polymerization inhibitor.

The polymerization inhibitor may include a hydroquinone-based compound, a catechol-based compound, or a combination thereof, but is not necessarily limited thereto. If (e.g. when) the curable composition according to some embodiments further includes the hydroquinone-based compound, the catechol-based compound, or the combination thereof, room temperature cross-linking during exposure after coating the curable composition may be prevented or reduced.

Examples of the hydroquinone-based compound, the catechol-based compound, or the combination thereof may be hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or one or more combinations thereof, but are not necessarily limited thereto.

The hydroquinone-based compound, the catechol-based compound, or the combination thereof may be utilized in a form of dispersion. The polymerization inhibitor in a form of dispersion may be included in an amount of about 0.001 wt % to about 3 wt %, for example about 0.01 wt % to about 2 wt % based on a total amount of the curable composition. If (e.g. when) the polymerization inhibitor is included in the ranges, passage of time at room temperature may be solved and concurrently (e.g., simultaneously) sensitivity deterioration and surface delamination phenomenon may be prevented or reduced.

In some embodiments, the curable composition according to some embodiments may further include malonic acid; 3-amino-1,2-propanediol; a silane-based coupling agent; a leveling agent; a fluorine-based surfactant; or a combination thereof in order to improve heat resistance and reliability.

For example, the curable composition according to some embodiments may further include a silane-based coupling agent having a reactive substituent such as a vinyl group, a carboxyl group, a methacryloxy group, an isocyanate group, an epoxy group, and/or the like in order to improve close contacting properties with a substrate.

Examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-(epoxycyclohexyl)ethyltrimethoxysilane, and/or the like, and these may be utilized alone or in a mixture of two or more.

The silane-based coupling agent may be utilized in an amount of about 0.01 parts by weight to about 10 parts by weight based on 100 parts by weight of the curable composition. If (e.g. when) the silane-based coupling agent is included within the range, close contacting properties, storage capability, and/or the like are improved.

In some embodiments, the curable composition may further include a surfactant, for example a fluorine-based surfactant as needed in order to improve coating properties and inhibit generation of spots, that is, improve leveling performance.

The fluorine-based surfactant may have a low weight average molecular weight of about 4,000 g/mol to about 10,000 g/mol, and specifically about 6,000 g/mol to about 10,000 g/mol. In some embodiments, the fluorine-based surfactant may have a surface tension of about 18 millinewton per meter (mN/m) to about 23 mN/m (measured in a 0.1% polyethylene glycol monomethylether acetate (PGMEA) solution). If (e.g. when) the fluorine-based surfactant has a weight average molecular weight and a surface tension within the described ranges, leveling performance may be further improved. For example, excellent or suitable characteristics may be provided if (e.g. when) slit coating as high-speed coating is applied because film defects may be less readily generated by preventing or reducing a spot generation during the high-speed coating and suppressing a vapor generation.

Examples of the fluorine-based surfactant may be BM-1000©, and BM-1100© (BM Chemie Inc.); MEGAFACE F 142D©, F 172©, F 173©, and F 183©Dainippon Ink Kagaku Kogyo Co., Ltd.); FULORAD FC-135©, FULORAD FC-170C©, FULORAD FC-430©, and FULORAD FC-431© (Sumitomo 3M Co., Ltd.); SURFLON S-112©, SURFLON S-113©, SURFLON S-131©, SURFLON S-141©, and SURFLON S-145© (ASAHI Glass Co., Ltd.); and SH-28PA©, SH-190©, SH-193©, SZ-6032©, and SF-8428©, and/or the like (Toray Silicone Co., Ltd.); F-482, F-484, F-478, F-554 and/or the like of DIC Co., Ltd.

In some embodiments, the curable composition according to some embodiments may include a silicone-based surfactant in addition to the fluorine-based surfactant. Examples of the silicone-based surfactant include, or may be, TSF400, TSF401, TSF410, TSF4440, and/or the like of Toshiba silicone Co., Ltd., but are not limited thereto.

The surfactant may be included in an amount of about 0.01 parts by weight to about 5 parts by weight, for example about 0.1 parts by weight to about 2 parts by weight based on 100 parts by weight of the curable composition. If (e.g. when) the surfactant is included within the ranges, foreign materials are less produced in a sprayed composition.

In some embodiments, the curable composition according to some embodiments may further include other additives such as an antioxidant, a stabilizer, and/or the like in a set or predetermined amount, unless properties are deteriorated.

### Solvent

In some embodiments, the curable composition according to some embodiments may be a solvent-type or kind curable composition further including a solvent.

Examples of the solvent may include alcohols such as methanol, ethanol, and/or the like; glycol ethers such as ethylene glycol methylether, ethylene glycol ethylether, propylene glycol methylether, and/or the like; cellosolve acetates such as methyl cellosolve acetate, ethyl cellosolve acetate, diethyl cellosolve acetate, and/or the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and/or the like; propylene glycol alkylether acetates such as propylene glycol monomethylether acetate, propylene glycol propylether acetate, and/or the like; ketones such as methylethylketone, cyclohexanone, 4-hydroxy-4-methyl-2-pentanone, methyl-n-propylketone, methyl-n-butylketone, methyl-n-amylketone, 2-heptanone, and/or the like; saturated aliphatic monocarboxylic acid alkyl esters such as ethyl acetate, n-butyl acetate, isobutyl acetate, and/or the like; lactate esters such as methyl lactate, ethyl lactate, and/or the like; hydroxy acetic acid alkyl esters such as methyl hydroxyacetate, ethyl hydroxyacetate, butyl hydroxyacetate, and/or the like; acetic acid alkoxyalkyl esters such as methoxymethyl acetate, methoxyethyl acetate, methoxybutyl acetate, ethoxymethyl acetate, ethoxyethyl acetate, and/or the like; 3-hydroxypropionic acid alkyl esters such as methyl 3-hydroxypropionate, ethyl 3-hydroxypropionate, and/or the like; 3-alkoxypropionic acid alkyl esters such as methyl 3-methoxypropionate, ethyl 3-methoxypropionate, ethyl 3-ethoxypropionate, methyl 3-ethoxypropionate, and/or the like; 2-hydroxypropionic acid alkyl ester such as methyl 2-hydroxypropionate, ethyl 2-hydroxypropionate, propyl 2-hydroxypropionate, and/or the like; 2-alkoxypropionic acid alkyl esters such as methyl 2-methoxypropionate, ethyl 2-methoxypropionate, ethyl 2-ethoxypropionate, methyl 2-ethoxypropionate, and/or the like; 2-hydroxy-2-methylpropionic acid alkyl esters such as methyl 2-hydroxy-2-methylpropionate, ethyl 2-hydroxy-2-methylpropionate, and/or the like; 2-alkoxy-2-methylpropionic acid alkyl esters such as methyl 2-methoxy-2-methylpropionate, ethyl 2-ethoxy-2-methylpropionate, and/or the like; esters such as 2-hydroxyethyl propionate, 2-hydroxy-2-methylethyl propionate, hydroxyethyl acetate, methyl 2-hydroxy-3-methylbutanoate, and/or the like; or ketonate esters such as ethyl pyruvate, and/or the like, and in addition, may be N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and/or the like, but is not limited thereto.

Examples of the solvent may be one or more of glycol ethers such as ethylene glycol monoethylether, ethylene diglycolmethylethylether, and/or the like; ethylene glycol alkylether acetates such as ethyl cellosolve acetate, and/or the like; esters such as 2-hydroxy ethyl propionate, and/or the like; carbitols such as diethylene glycol monomethylether, and/or the like; propylene glycol alkylether acetates such as propylene glycol monomethylether acetate, propylene glycol propylether acetate, and/or the like; alcohols such as ethanol, and/or the like, or one or more combinations thereof.

For example, the solvent may be a polar solvent including propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, or a combination thereof.

The solvent may be included in an amount of about 40 wt % to about 80 wt %, for example, about 45 wt % to about 80 wt %, based on a total amount of the curable composition. If (e.g. when) the solvent is within the described range, the solvent-type or kind curable composition has appropriate or suitable viscosity and thus may have excellent or suitable coating properties if (e.g. when) coated in a large area through spin-coating and slit-coating.

Other embodiments provide a cured layer produced utilizing the aforementioned curable composition, and a display device including the cured layer.

One of the methods for producing the cured layer includes coating the curable composition and solvent-type or kind curable composition on a substrate utilizing an ink-jet spraying method to form a pattern (S1); and curing the pattern (S2).

### (S1) Formation of Pattern

The curable composition may be coated to be about 0.5 micrometer (μm) to about 20 μm on a substrate in an ink-jet spraying method. The ink-jet spraying method may form a pattern by spraying a single color per each nozzle and thus repeating the spraying as many times as the needed number of colors, but the pattern may be formed by concurrently (e.g., simultaneously) spraying the needed number of colors through each ink-jet nozzle in order to reduce processes.

### (S2) Curing

The obtained pattern is cured to obtain a pixel. Herein, the curing method may be thermal curing or photocuring process. The thermal curing process may be performed at greater than or equal to about 100° C., desirably, in a range of about 100° C. to about 300° C., and more desirably, in a range of about 160° C. to about 250° C. The photocuring process may include irradiating an actinic ray such as a UV ray of about 190 nm to about 450 nm, for example about 200 nm to about 400 nm. The irradiating is performed by utilizing a light source such as a mercury lamp with a low pressure, a high pressure, or an ultrahigh pressure, a metal halide lamp, an argon gas laser, and/or the like. An X ray, an electron beam, and/or the like may be also utilized as needed.

In some embodiments, a method of producing the cured layer may include producing a cured layer utilizing the aforementioned curable composition by a lithography method as follows.

### (1) Coating and Film Formation

The aforementioned curable composition may be coated to have a desired or suitable thickness, for example, a thickness in a range of about 2 μm to about 10 μm, on a substrate which undergoes a set or predetermined pretreatment, utilizing a spin or slit coating method, a roll coating method, a screen-printing method, an applicator method, and/or the like. Then, the coated substrate may be heated at a temperature of about 70° C. to about 90° C. for about 1 minute to about 10 minutes to remove a solvent and to form a film.

### (2) Exposure

The resultant film may be irradiated by an actinic ray such as a UV ray of about 190 nm to about 450 nm, for example about 200 nm to about 500 nm after putting a mask with a set or predetermined shape to form a desired or suitable pattern. The irradiating is performed by utilizing a light source such as a mercury lamp with a low pressure, a high pressure, or an ultrahigh pressure, a metal halide lamp, an argon gas laser, and/or the like. An X ray, an electron beam, and/or the like may be also utilized as needed.

Exposure process uses, for example, a light dose of 500 millijoule per square centimeter (mJ/cm²) or less (with a 365 nm sensor) if (e.g. when) a high-pressure mercury lamp is utilized. However, the light dose may vary depending on types (kinds) of each component of the curable composition, its combination ratio, and a dry film thickness.

### (3) Development

After the exposure process, an alkali aqueous solution may be utilized to develop the exposed film by dissolving and removing an unnecessary part except the exposed part, forming an image pattern. In other words, if (e.g. when) the alkali developing solution is utilized for the development, a non-exposed region may be dissolved, and an image color filter pattern may be formed.

### (4) Post-Treatment

The developed image pattern may be heated again or irradiated by an actinic ray and/or the like for curing, in order to accomplish excellent or suitable quality in terms of heat resistance, light resistance, close contacting properties, crack-resistance, chemical resistance, high strength, storage stability, and/or the like.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

A display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinafter, the present disclosure is illustrated in more detail with reference to examples. These examples, however, are not in any sense to be interpreted as limiting the scope of the present disclosure.

### EXAMPLES

### Preparation of Compounds

### Preparation Example 1

In a 100 mL round flask, after dissolving 54 g of 9,9-Bis(4-glycidyloxyphenyl)fluorene and 45.6 g of 2,2′,6,6′-tetramethyl-4,4′-biphenol were dissolved in PGMEA (polyethylene glycol monomethylether acetate), 0.1 g of TBAB (tetrabutyl ammonium bromide) was added thereto and then, stirred at 100° C. for 24 hours and washed with methanol and water, and precipitates formed therefrom were dried, preparing a compound (having a weight average molecular weight: 5,000 g/mol) including both (e.g., simultaneously) of the structural units represented by Chemical Formulas E-1 and E-2.

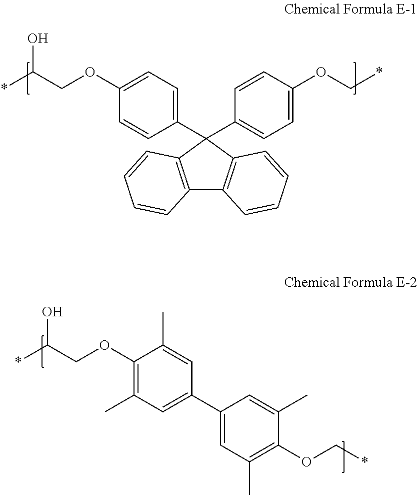

### Preparation Example 2

In a 100 mL round flask, after dissolving 54 g of bisphenol A and 32 g of 2,2′-[1,6-Naphthalenediylbis(oxymethylene)]dioxirane in PGMEA, 0.1 g of TBAB (tetrabutyl ammonium bromide) was added thereto and then, stirred at 100° C. for 24 hours and washed with methanol and water, and precipitates formed therefrom were dried, preparing a compound (having a weight average molecular weight: 4,500 g/mol) including both (e.g., simultaneously) of the structural units represented by Chemical Formulas E-3 and E-4.

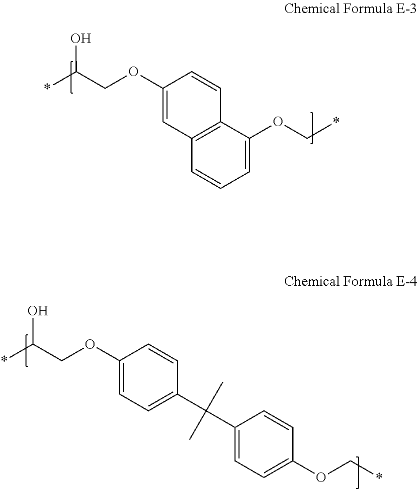

### Preparation Example 3

In a 100 mL round flask, after dissolving 54 g of 2,2′-(naphthalene-1,6-diylbis(oxy))bis(methylene)dioxirane and 32 g of naphthalene-2,3-diol in PGMEA, 0.1 g of TBAB (tetrabutyl ammonium bromide) was added thereto and then, stirred at 100° C. for 24 hours and washed with methanol and water, and precipitates formed therefrom were dried, preparing a compound (having a weight average molecular weight: 3,500 g/mol) including both (e.g., simultaneously) of the structural units represented by Chemical Formulas E-1 and E-3.

### Comparative Preparation Example 1

A compound (having a weight average molecular weight: 3,000 g/mol) including the structural unit represented by Chemical Formula E-1 alone was prepared in substantially the same manner as in Preparation Example 1 except that the 2,2′,6,6′-tetramethyl-4,4′-biphenol was not utilized, so that the structural unit represented by Chemical Formula E-2 was not included.

### Comparative Preparation Example 2

A compound (a weight average molecular weight: 5,000 g/mol) including the structural unit represented by Chemical Formula E-2 alone was prepared in substantially the same manner as in Preparation Example 1 except that the 2,2′-(naphthalene-1,6-diylbis(oxy))bis(methylene)dioxirane was not utilized.

### Comparative Preparation Example 3

A compound (a weight average molecular weight: 3,500 g/mol) including the structural unit represented by Chemical Formula E-3 alone was prepared in substantially the same manner as in Preparation Example 2 except that the naphthalene-2,3-diol was not utilized.

### Comparative Preparation Example 4

A compound (a weight average molecular weight: 5,000 g/mol) including the structural unit represented by Chemical Formula E-4 alone was prepared in substantially the same manner as in Preparation Example 2 except that the bisphenol A was not utilized.

### Preparation of Surface-modified Quantum Dot Dispersion

### Preparation Example 4

After putting a magnetic bar in a 3-necked round bottom flask, a green quantum dot dispersion solution (having a quantum dot solid: 23 wt %, InP/ZnSe/ZnS, Hansol Chemical Co., Ltd.) was added thereto. Subsequently, a compound represented by Chemical Formula Q (ligand) was added thereto and then, stirred at 80° C. under a nitrogen atmosphere. If (e.g. when) a reaction was completed, the quantum dot reaction was cooled to room temperature (23° C.) and added to cyclohexane to produce (e.g., catch) precipitates. The precipitates were separated from the cyclohexane through centrifugation and sufficiently dried in a vacuum oven for 24 hours, obtaining surface-modified quantum dots.

The surface-modified green quantum dots were stirred with (e.g., in) a polymerizable compound for 12 hours, obtaining surface-modified quantum dot dispersion (QD solid: 23 wt %).

Synthesis of Compound represented by Chemical Formula Q: 100 g of PH-4 (Hannong Chemicals Inc.) was put in a two-necked round bottom flask and sufficiently dissolved in 300 mL of THE. Subsequently, 15.4 g of NaOH was added to 100 mL of water at 0° C. and then, dissolved therein, until a transparent solution was obtained. Then, a solution obtained by dissolving 73 g of para-toluene sulfonic chloride in 100 mL of THE was slowly injected thereinto at 0° C. Herein, the injection proceeded for 1 hour, and the obtained mixture was stirred at room temperature for 12 hours. If (e.g. when) a reaction was completed, an excessive amount of methylene chloride was added thereto and then, stirred, and a NaHCO₃ saturated solution was added thereto and then, proceeded with extraction, titration, and moisture removal. After removing the solvent, drying was performed in a dry oven for 24 hours. 50 g of the dried product was put in a two-necked round bottom flask and sufficiently stirred with (e.g., in) 300 mL of ethanol. Subsequently, 27 g of thiourea was added thereto and dispersed and then, the mixture was refluxed at 80° C. for 12 hours. Then, an aqueous solution obtained by dissolving 4.4 g of NaOH in 20 mL of water was injected thereinto, while further stirring for 5 hours, an excessive amount of methylene chloride was added thereto and then, stirred, and a hydrochloric acid aqueous solution was added thereto and then, proceeded sequentially with extraction, titration, moisture removal, and solvent removal. Subsequently, drying in a vacuum oven for 24 hours was performed, obtaining a compound represented by Chemical Formula Q.

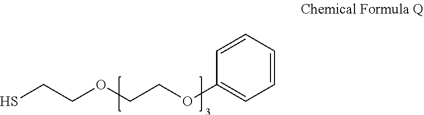

### Preparation of Curable Compositions

### Examples 1 to 3 and Comparative Examples 1 to 5

Each curable composition of Examples 1 to 3 and Comparative Examples 1 to 5 was prepared to have a composition shown in Table 1 by utilizing the following components.

For example, the quantum dot dispersion was measured and mixed and diluted with a polymerizable compound, and each of the compounds of the preparation examples and the comparative preparation examples and a polymerization inhibitor were added thereto and then, stirred for 5 minutes. Subsequently, a photo-initiator was added thereto, and a light diffusing agent was added thereto. Then, the corresponding crude composition was stirred for 1 hour, preparing a curable composition.

### (A) Quantum Dots

Surface-modified green quantum dot dispersion produced from Preparation Example 4

### (B) Polymerizable Compound

Compound represented by Chemical Formula 3-1 (M200, Miwon Chemical Co.)

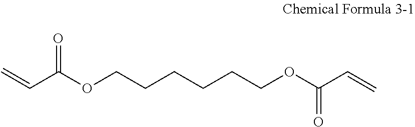 [SMILES: C=CC(=O)OCCCCCCOC(=O)C=C]

### (C) Compound

(C-1) Compound of Preparation Example 1
(C-2) Compound of Preparation Example 2
(C-3) Compound of Preparation Example 3
(C-4) Compound of Comparative Preparation Example 1
(C-5) Compound of Comparative Preparation Example 2
(C-6) Compound of Comparative Preparation Example 3
(C-7) Compound of Comparative Preparation Example 4

### (D) Photopolymerization Initiator

TPO-L (Polynetron)

### (E) Light Diffusing Agent

Titanium dioxide dispersion (TiO₂ solid content (e.g., amount): 20 wt %, average particle diameter: 200 nm, Ditto Technology Co., Ltd.)

### (F) Polymerization Inhibitor

Methylhydroquinone (TOKYO CHEMICAL Co., Ltd.)

TABLE 1
unit: wt %

| | | | | | Comp. | Comp. | Comp. | Comp. | Comp. |
|---|---|---|---|---|---|---|---|---|---|
| | | Ex. 1 | Ex. 2 | Ex. 3 | Ex. 1 | Ex. 2 | Ex. 3 | Ex. 4 | Ex. 5 |
| (A) Quantum dot dispersion | | 41 | 41 | 41 | 41 | 41 | 41 | 41 | 41 |
| (B) Polymerizable compound | | 35.3 | 35.3 | 35.3 | 35.3 | 35.3 | 35.3 | 35.3 | 53.3 |
| (C) Compound | (C-1) | 18 | — | — | — | — | — | — | — |
| | (C-2) | — | 18 | — | — | — | — | — | — |
| | (C-3) | — | — | 18 | — | — | — | — | — |
| | (C-4) | — | — | — | 18 | — | — | — | — |
| | (C-5) | — | — | — | — | 18 | — | — | — |
| | (C-6) | — | — | — | — | — | 18 | — | — |
| | (C-7) | — | — | — | — | — | — | 18 | — |

| | | | | | | | | |
|---|---|---|---|---|---|---|---|---|
| (C) Photopolymerization | 1.5 | 1.5 | 1.5 | 1.5 | 1.5 | 1.5 | 1.5 | 1.5 |
| initiator | | | | | | | | |
| (D) Light diffusing agent | 4 | 4 | 4 | 4 | 4 | 4 | 4 | 4 |
| (E) Polymerization inhibitor | 0.2 | 0.2 | 0.2 | 0.2 | 0.2 | 0.2 | 0.2 | 0.2 |

### Evaluation 1: Ink Viscosity

Each of the curable compositions of Examples 1 to 3 and Comparative Examples 1 to 5 was measured with respect to viscosity at 25° C. by utilizing a viscometer (RV-2 spins, 23 rpm, DV-II, Ametek Brookfield), and the results are shown in Table 2.

TABLE 2
unit: centipoise (cPs)

| | | | | Comp. | Comp. | Comp. | Comp. | Comp. |
|---|---|---|---|---|---|---|---|---|
| | Ex. 1 | Ex. 2 | Ex. 3 | Ex. 1 | Ex. 2 | Ex. 3 | Ex. 4 | Ex. 5 |
| Viscosity | 16.2 | 18.5 | 17.5 | 26.0 | 28.5 | 30.1 | 32.1 | 3.8 |

### Evaluation 2: Evaluation of Optical Characteristics (Light Resistance Reliability)

Each of the solvent-free curable compositions of Examples 1 to 3 and Comparative Examples 1 to 5 was spin-coated to be 10 micrometer (μm) thick on a yellow photoresist (YPR) by utilizing a spin coater (830 rpm, 5 seconds, Opticoat MS-A150, Mikasa Co., Ltd.) and exposed to light with 5000 millijoule (mJ) (83° C., 10 seconds) under a nitrogen atmosphere by utilizing a UV exposer at 395 nanometer (nm). Subsequently, a 2 centimeter (cm)×2 cm single film specimen therefrom was loaded in an integrating sphere equipment (QE-2100, Otsuka Electronics, Co., Ltd.) and dried at 180° C. under a nitrogen atmosphere in a drying furnace for 30 minutes and then, measured with respect to light efficiency at 100-hour intervals, and the results are shown in Table 3.

TABLE 3

| | | | | | Comp. | Comp. | Comp. | Comp. | Comp. |
|---|---|---|---|---|---|---|---|---|---|
| | | Ex. 1 | Ex. 2 | Ex. 3 | Ex. 1 | Ex. 2 | Ex. 3 | Ex. 4 | Ex. 5 |
| Light | Initial | 33.5 | 33.3 | 32.8 | 33.2 | 33.3 | 32.7 | 32.2 | 32 |
| efficiency | After 100 hours | 33.0 | 33.2 | 32.6 | 32.5 | 31.1 | 31.4 | 30.9 | 28.1 |
| (%) | After 200 hours | 33.2 | 33.3 | 32.6 | 31.3 | 28.2 | 29 | 27.5 | 22.9 |
| | After 300 hours | 33.0 | 32.9 | 32.1 | 27.1 | 24.1 | 26.1 | 23.7 | 15.2 |
| | After 400 hours | 32.0 | 32.7 | 31.9 | 24 | 19 | 21.6 | 19.2 | 8.8 |

Referring to Tables 2 and 3, the curable composition according to some embodiments exhibited excellent or suitable light resistance reliability as well as maintained viscosity of 5 cPs to 20 cPs at the same time.

While this present disclosure has been described in connection with what is presently considered to be practical example embodiments, it is to be understood that the present disclosure is not limited to the disclosed embodiments, but, on the contrary, is intended to cover one or more suitable modifications and equivalent arrangements included within the spirit and scope of the appended claims and equivalents thereof. Therefore, the aforementioned embodiments should be understood to be example but not limiting the present disclosure in any way.

What is claimed is:

1. A curable composition, comprising:
(A) quantum dots;
(B) a polymerizable compound; and
(C) a compound comprising a structural unit represented by Chemical Formula 1 and a structural unit represented by Chemical Formula 2: 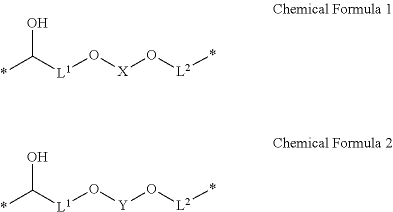
wherein, in Chemical Formulas 1 and 2,
L¹ and L² are each independently a substituted or unsubstituted C1 to C20 alkylene group, and
X and Y are each independently a substituted or unsubstituted C6 to C20 arylene group or a divalent linking group comprising a substituted or unsubstituted C6 to C20 arylene group, and
wherein X and Y are different from each other.

2. The curable composition as claimed in claim 1, wherein
X and Y are each independently represented by any one of Chemical Formulas L-1 to L-14: 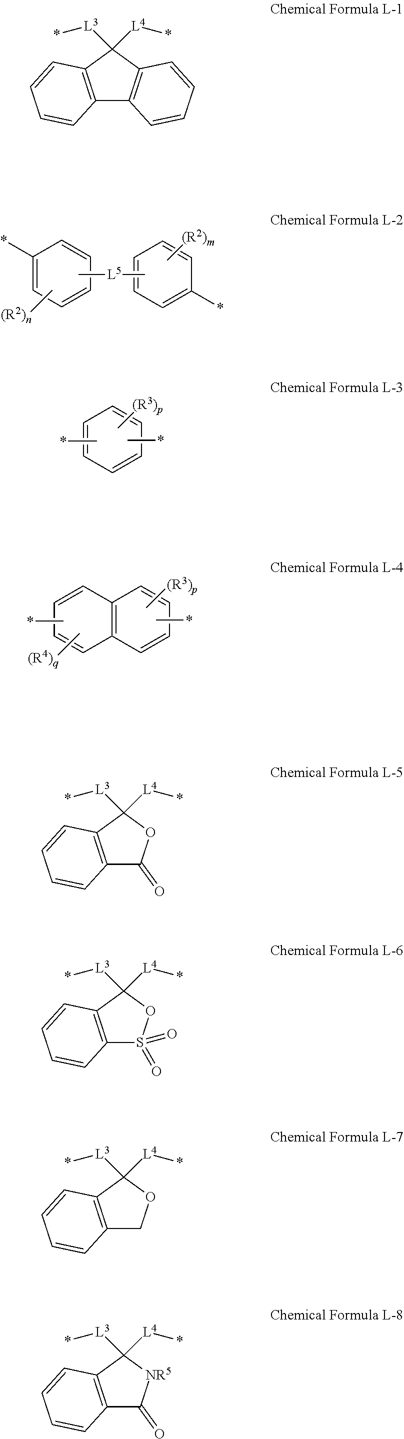 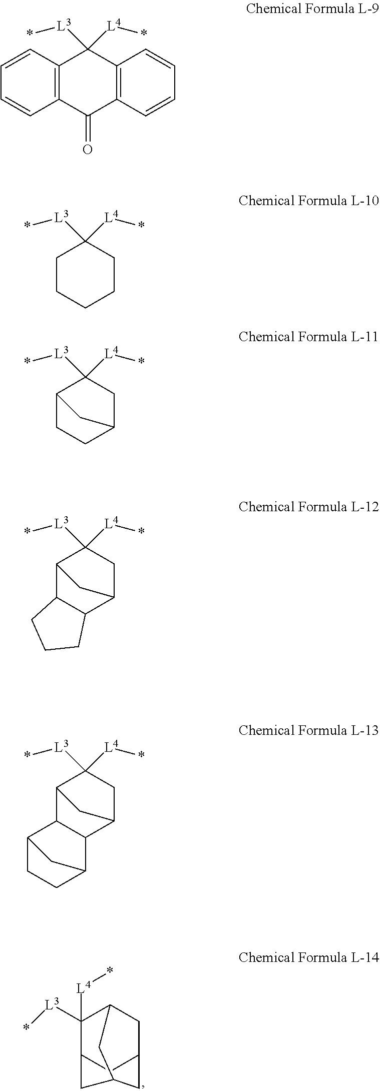
wherein, in Chemical Formulas L-1 to L-14,
L³ and L⁴ are each independently a substituted or unsubstituted C6 to C20 arylene group,
L⁵ is a single bond, a substituted or unsubstituted C1 to C20 alkylene group, or a substituted or unsubstituted C6 to C20 arylene group,
R¹ to R⁵ are each independently a hydrogen atom, a substituted or unsubstituted C1 to C20 alkyl group, a vinyl group, or a substituted or unsubstituted C6 to C20 aryl group, and
m, n, p, and q are each independently an integer of 0 to 3.

3. The curable composition as claimed in claim 2, wherein
X and Y are each independently represented by any one of Chemical Formulas L-1 to L-4.

4. The curable composition as claimed in claim 1, wherein
the compound comprising the structural unit represented by Chemical Formula 1 and the structural unit represented by Chemical Formula 2 has a weight average molecular weight of about 1,000 g/mol to about 30,000 g/mol.

5. The curable composition as claimed in claim 1, wherein
the compound comprising the structural unit represented by Chemical Formula 1 and the structural unit represented by Chemical Formula 2 is comprised in an amount of about 1 wt % to about 40 wt %, based on a total amount of solids of the curable composition.

6. The curable composition as claimed in claim 1, wherein
the polymerizable compound further comprises a compound represented by Chemical Formula 3: 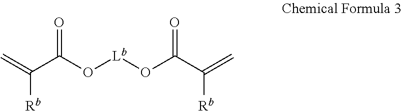
wherein, in Chemical Formula 3,
each R^{b} independently is a hydrogen atom or a methyl group, and
L^{b} is a substituted or unsubstituted C1 to C30 alkylene group or *-L^{c}-O-L^{d}-*, and wherein L^{c} and L^{d} are each independently a substituted or unsubstituted C1 to C20 alkylene group.

7. The curable composition as claimed in claim 6, wherein
the compound represented by Chemical Formula 3 is represented by Chemical Formula 3-1 or 3-2:

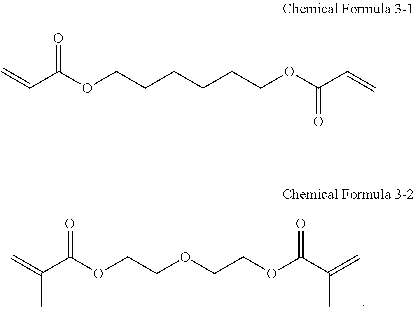

8. The curable composition as claimed in claim 1, wherein
the quantum dots are surface-modified quantum dots represented by at least one of Chemical Formulas 4 to 17: 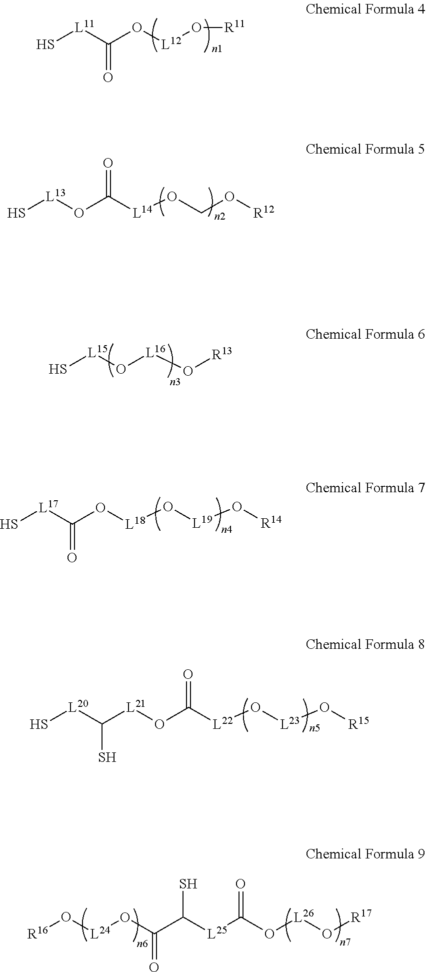
wherein, in Chemical Formulas 4 to 9,
R¹¹ to R¹⁷ are each independently a substituted or unsubstituted C1 to C10 alkyl group or a substituted or unsubstituted C6 to C20 aryl group,
L¹¹ to L²⁶ are each independently a substituted or unsubstituted C1 to C10 alkylene group, and
n1 to n7 are each independently an integer of 0 to 10, 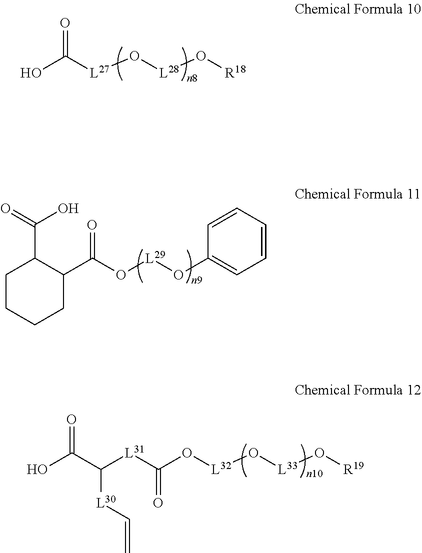
wherein, in Chemical Formulas 10 to 12,
R¹⁸ and R¹⁹ are each independently a substituted or unsubstituted C1 to C10 alkyl group,
L²⁷ to L³³ are each independently a substituted or unsubstituted C1 to C10 alkylene group, and
n8 to n10 are each independently an integer of 0 to 10, 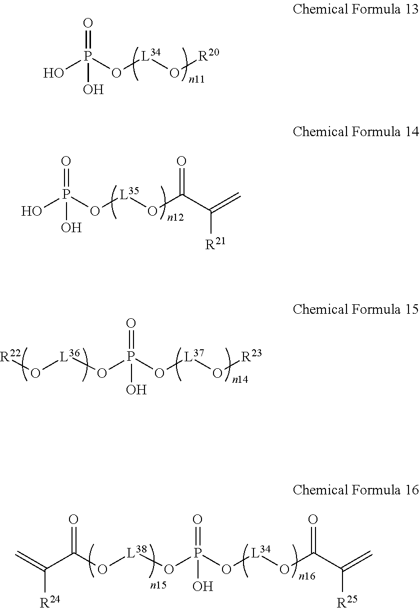
wherein, in Chemical Formulas 13 to 16,
R²⁰ to R²⁵ are each independently a hydrogen atom or a substituted or unsubstituted C1 to C10 alkyl group,
L³⁴ to L³⁹ are each independently a substituted or unsubstituted C1 to C10 alkylene group, and
n11 to n16 are each independently an integer of 0 to 10, 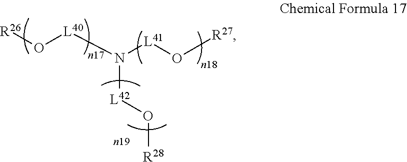
and
wherein, in Chemical Formula 17,
R²⁶ to R²⁸ are each independently a substituted or unsubstituted C1 to C10 alkyl group,
L⁴⁰ to L⁴² are each independently a substituted or unsubstituted C1 to C10 alkylene group, and
n17 to n19 are each independently an integer of 0 to 10.

9. The curable composition as claimed in claim 1, wherein
the quantum dots have a maximum fluorescence emission wavelength at about 500 nm to about 680 nm.

10. The curable composition as claimed in claim 1, wherein
the curable composition is a solvent-free curable composition.

11. The curable composition as claimed in claim 10, wherein
the quantum dots are in an amount of about 5 wt % to about 70 wt %, based on a total weight of the solvent-free curable composition.

12. The curable composition as claimed in claim 10, wherein
the polymerizable compound is included in an amount of about 30 wt % to about 95 wt %, based on a total weight of the solvent-free curable composition.

13. The curable composition as claimed in claim 1, wherein
the curable composition further comprises a polymerization initiator, a light diffusing agent, or a combination thereof.

14. The curable composition as claimed in claim 13, wherein
the light diffusing agent comprises barium sulfate, calcium carbonate, titanium dioxide, zirconia, or a combination thereof.

15. The curable composition as claimed in claim 1, wherein
the curable composition further comprises a solvent.

16. The curable composition as claimed in claim 15, wherein
the curable composition comprises:
about 1 wt % to about 40 wt % of the (A) quantum dots;
about 1 wt % to about 20 wt % of the (B) polymerizable compound;
about 0.1 wt % to about 20 wt % of the (C) compound comprising the structural unit represented by Chemical Formula 1 and the structural unit represented by Chemical Formula 2; and
about 40 wt % to about 80 wt % of the solvent, based on a total weight of the curable composition.

17. The curable composition as claimed in claim 1, wherein
the curable composition further comprises a polymerization inhibitor; malonic acid; 3-amino-1,2-propanediol; a silane-based coupling agent; a leveling agent; a fluorine-based surfactant; or a combination thereof.

18. A cured layer produced using the curable composition as claimed in claim 1.

19. A display device comprising the cured layer as claimed in claim 18.
